(19) United States
(12) Patent Application Publication
(10) Pub. No.: US 2023/0326102 A1
(43) Pub. Date: Oct. 12, 2023

(54) SYSTEM, METHOD, AND COMPUTER-ACCESSIBLE MEDIUM FOR FACILITATING SINGLE ECHO RECONSTRUCTION OF RAPID MAGNETIC RESONANCE IMAGING

(71) Applicant: The Trustees of Columbia University in the City of New York, New York, NY (US)

(72) Inventors: John Thomas VAUGHAN, New York, NY (US); Sairam GREETHANATH, New York, NY (US)

(21) Appl. No.: 18/209,800

(22) Filed: Jun. 14, 2023

Related U.S. Application Data
(63) Continuation of application No. PCT/US21/63616, filed on Dec. 15, 2021.
(60) Provisional application No. 63/125,658, filed on Dec. 15, 2020.

(51) Int. Cl. G06T 11/00; G06T 5/00

(52) U.S. Cl. CPC G06T 11/006; G06T 5/003; G06T 2207/10088; G06T 2207/20081

(57) ABSTRACT

An exemplary system, method, and computer-accessible medium for reconstructing a portion(s) of an image(s) of a patient(s) can include, for example, receiving magnetic resonance imaging (MRI) information for the patient(s), generating a plurality of coil sensitivity weighted projections based on the MRI information, inverting a column in the coil sensitivity weighted projections to generate inverted column information, and reconstructing the portion(s) of the image(s) based on the inverted column information. The portion(s) of the image(s) can be deblurred, for example, using a deep learning procedure(s). A reference scan of a part(s) of the patient(s) can be received, and deep learning procedure(s) can be trained based on the reference scan.

### CROSS-REFERENCE TO RELATED APPLICATION(S)

This application relates to and claims priority from U.S. Patent Application No. 63/125,658, filed on Dec. 15, 2020, the entire disclosure of which is incorporated herein by reference.

### FIELD OF THE DISCLOSURE

The present disclosure relates generally to magnetic resonance imaging (“MRI”), and more specifically, to exemplary embodiments of an exemplary system, method, and computer-accessible medium for facilitating a single echo reconstruction (“SER”) of a rapid MRI.

### BACKGROUND INFORMATION

Acquisition time of a two-dimensional (“2D”) magnetic resonance (“MR”) image can depend on repetition time, number of views, or phase encodes for Cartesian imaging, and number of signal averages (e.g., T_{acq}=TR*Nᵥ*NSA). Further, the acquisition speed can be subject to radio-frequency (“RF”) power deposition, peripheral nerve stimulation (“PNS”), and gradient noise constraints. Reconstructing a 2D MR image from a single echo can mitigate these multiple constraints. However, previous formulations (see, e.g., References 1 and 2) using single echo acquisitions with a short Cartesian readout may require the number of receive channels using stripline coils to equal to Nᵥ; or to use external magnetosensors. (See, e.g., Reference 3).

Thus, it may be beneficial to provide an exemplary system, method, and computer-accessible medium for the SER of rapid MRI which can overcome at least some of the deficiencies described herein above.

### SUMMARY OF EXEMPLARY EMBODIMENTS

An exemplary system, method, and computer-accessible medium for reconstructing a portion(s) of an image(s) of a patient(s) can include, for example, receiving magnetic resonance imaging (MRI) information for the patient(s), generating a plurality of coil sensitivity weighted projections based on the MRI information, inverting a column in the coil sensitivity weighted projections to generate inverted column information, and reconstructing the portion(s) of the image(s) based on the inverted column information. The portion(s) of the image(s) can be deblurred, for example, using a deep learning procedure(s). A reference scan of a part(s) of the patient(s) can be received, and deep learning procedure(s) can be trained based on the reference scan. A plurality of training images can be generated by varying at least one of (i) an amplitude of the reference scan, or (ii) a noise level of the reference scan, and the deep learning procedure(s) can be trained based on the training images.

In some exemplary embodiments of the present disclosure, a further column in the coil sensitivity weighted projections can be inverted to generate further inverted column information, a further portion(s) of the image(s) can be generated based on the further inverted column information, and these procedures can be repeated until the image(s) is reconstructed in its entirety.

In some exemplary embodiments of the present disclosure, the MRI information can include a signal collected over a time t and channels q. In some exemplary embodiments of the present disclosure, the signal can include a coil sensitivity for each location of each of the channels q. In some exemplary embodiments of the present disclosure, the plurality of coil sensitivity weighted projections can be generated using a discrete Fourier transform of the signal. In some exemplary embodiments of the present disclosure, the computing arrangement can be further configured to concatenate the plurality of coil sensitivity weighted projections. In some exemplary embodiments of the present disclosure, the inverting of the column in the plurality of coil sensitivity weighted projections can comprise inverting coil sensitivities for a particular column for all rows and the channels q. In some exemplary embodiments of the present disclosure, the inverted column information includes line-intensity profiles.

These and other objects, features and advantages of the exemplary embodiments of the present disclosure will become apparent upon reading the following detailed description of the exemplary embodiments of the present disclosure, when taken in conjunction with the appended claims.

### BRIEF DESCRIPTION OF THE DRAWINGS

Further objects, features and advantages of the present disclosure will become apparent from the following detailed description taken in conjunction with the accompanying FIGS. showing illustrative embodiments of the present disclosure, in which:

FIGS. 1A and 1B are exemplary diagrams of an exemplary acquisition associated with an exemplary single echo reconstruction (“SER”) protocol according to an exemplary embodiment of the present disclosure;

FIGS. 2A-2G are exemplary images of an exemplary reconstruction using the exemplary system, method, and computer-accessible medium according to an exemplary embodiment of the present disclosure;

FIGS. 3A-3I are exemplary images illustrating spatially varying point spread function deblurring according to an exemplary embodiment of the present disclosure;

FIG. 4 is a set of exemplary images comparing the exemplary SER with other reconstruction methods according to an exemplary embodiment of the present disclosure;

FIGS. 5A-5C are graphs comparing the performance of the exemplary SER with other methods according to an exemplary embodiment of the present disclosure;

FIG. 6 is an exemplary reconstruction procedure according to an exemplary embodiment of the present disclosure;

FIG. 7 is an illustration of exemplary coil sensitivity weighted projections according to an exemplary embodiment of the present disclosure;

FIG. 8 is an illustration of an exemplary spatially varying PSF procedure according to an exemplary embodiment of the present disclosure;

FIGS. 9A-9C are exemplary error quantification graphs according to an exemplary embodiment of the present disclosure;

FIG. 10 is a set of illustrations of exemplary test results according to an exemplary embodiment of the present disclosure;

FIG. 11 is a set of illustrations of exemplary retrospective images according to an exemplary embodiment of the present disclosure;

FIG. 12 is a set of illustrations of exemplary SEASR contrast experiments according to an exemplary embodiment of the present disclosure;

FIGS. 13A-13C is a set of illustrations of exemplary SEASR contrast graphs according to an exemplary embodiment of the present disclosure;

FIG. 14 illustrates a table listing exemplary advantages of SEASR procedure according to an exemplary embodiment of the present disclosure;

FIG. 15 illustrates an exemplary neural network architecture according to an exemplary embodiment of the present disclosure;

FIG. 16 illustrates an exemplary training procedure according to an exemplary embodiment of the present disclosure;

FIG. 17 illustrates an exemplary test results according to an exemplary embodiment of the present disclosure; and

FIG. 18 is an illustration of an exemplary block diagram of an exemplary system in accordance with certain exemplary embodiments of the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF EXEMPLARY EMBODIMENTS

The exemplary system, method, and computer-accessible medium, according to an exemplary embodiment of the present disclosure, can utilize reconstruction-only approach, referred to as single echo reconstruction (“SER”) to facilitate rapid 128×128 MR imaging using a 64-channel coil without phase encoding, for example, T_{acq}=T_{encode}*NSA, where T_{encode} can be the time to acquire one echo. The exemplary system, method, and computer-accessible medium can facilitate significant reduction of RF power, PNS, and gradient noise. A commercially available coil with no external sensors can be utilized, and the results of the exemplary system, method, and computer-accessible medium can be compared with gold standard (“GS”) 2D spin-echo (“SE”) and accelerated acquisitions T₂ for weighted imaging as an application.

### Exemplary Acquisition

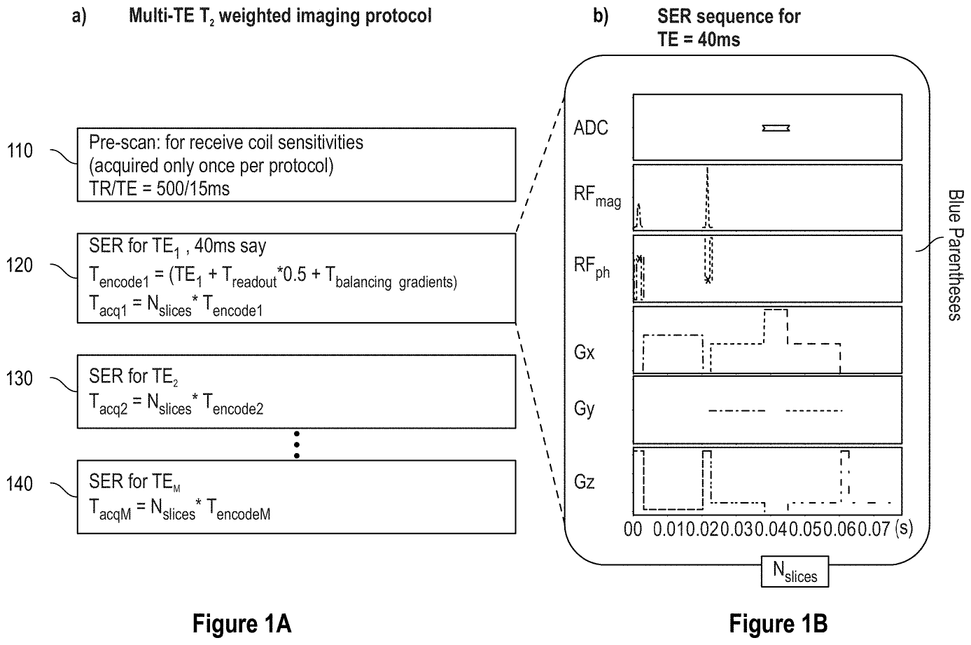

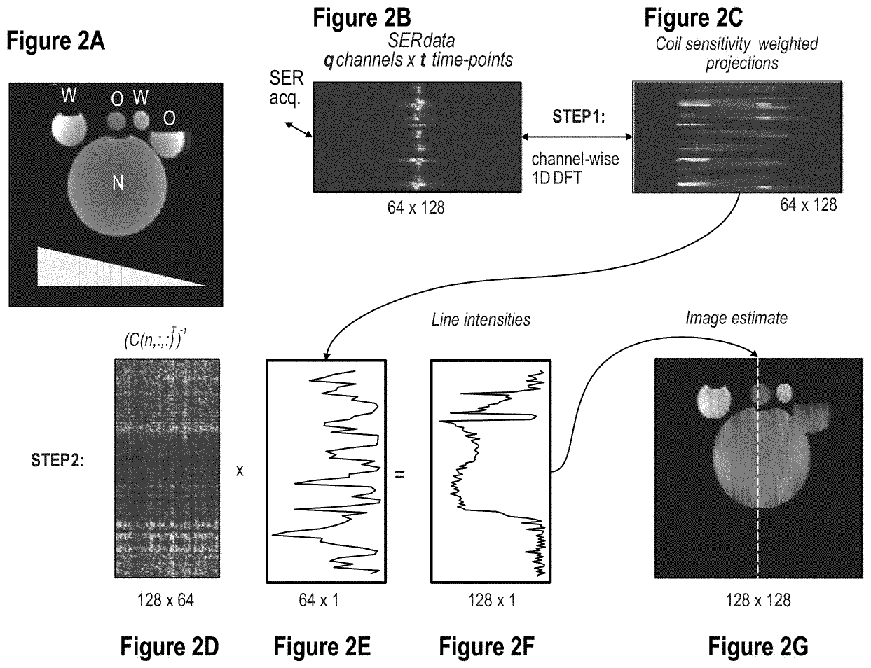

An in vitro phantom (see, e.g., FIG. 2A) was used to evaluate acquisition performance and image reconstruction. The GS procedure included a 2D multi-slice SEacquired at two different echo times (e.g., TE=40 ms, 80 ms). Accelerated sequences included turbo SE (“TSE”) with a Generalized Autocalibrating Partial Parallel Acquisition (“GRAPPA”) factor of 6, an echo-train-length of 7 and, the half Fourier acquisition single-shot TSE (“HASTE”). The SER protocol and pulse sequence are shown in FIGS. 1A and 1B.

For example, FIG. 1A provides an illustration of an exemplary block diagram of a Multi-TE T₂ weighted imaging protocol according to an exemplary embodiment of the present disclosure. In some example embodiments, an SER protocol may require one pre-scan for coil sensitivities (e.g., procedure 110). An exemplary application to multi-TE imaging can include acquiring SER data with different TE with the encoding time (T_{encode}) shown in the blue boxes (e.g., procedures 120, 130, and 140). (T_{encode}) may not be dependent on TR or the number of views but it may be dependent on TE. In some examples, the number of signal averages can be one. FIG. 1B provides an illustration of SER sequence for TE=40 ms according to an exemplary embodiment of the present disclosure. FIG. 1B can show an exemplary pypulseq (4,5) SER pulse sequence timing diagram with no phase encoding (Gy=0). Multi-slice implementation can involve repeating the block in blue parentheses for N_{slices} number of slices. In the exemplary embodiment of FIG. 1B, N_{slices} can be 11.

For example, the pypulseq coded sequence can acquire the central line in Cartesian k-space (phase encoding=0). (See, e.g., References 4 and 5). The reference scan was a pypulseq 2D SE multi-slice with TR/TE=500/15 ms. All acquisitions were acquired using a 64-channel head coil, had a field-of-view of 256×256 mm², slice thickness=5 mm, and eleven slices. The GS, accelerated sequences, and SER were evaluated for acquisition time, total RF power deposited, PNS stimulation, and contrast compared to GS.

### Exemplary Reconstruction

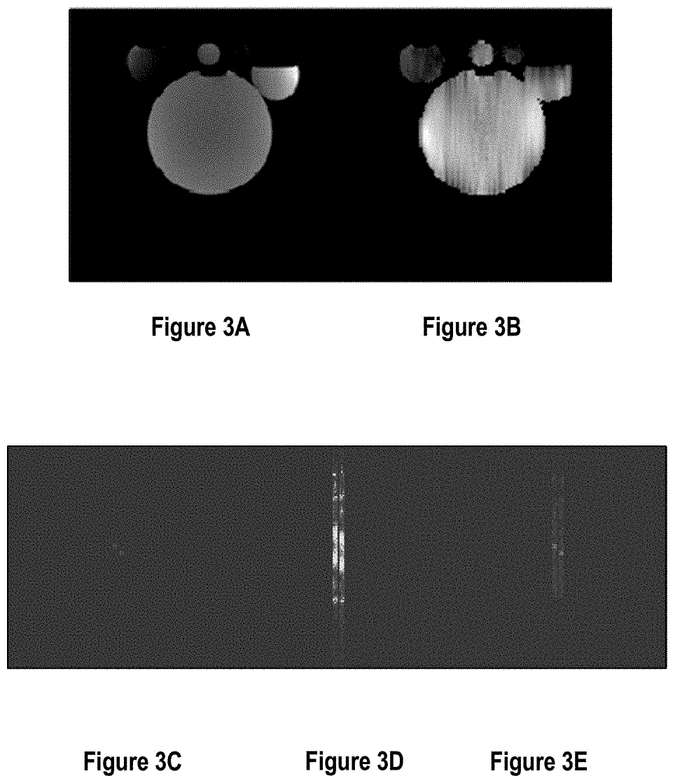

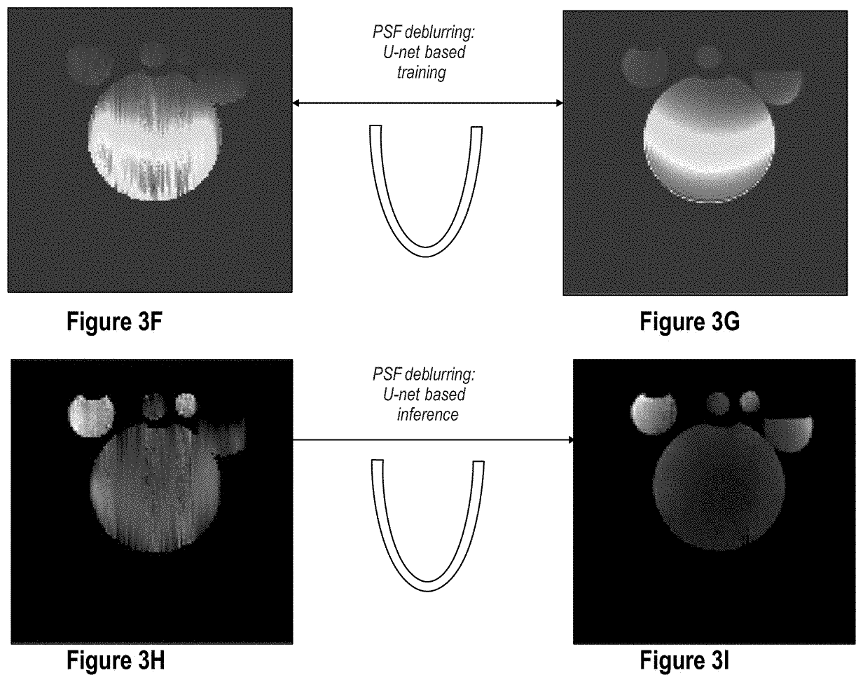

The exemplary SER procedure shown in FIGS. 2A-2G and 3A-3G include three exemplary procedures. For example, S can be the signal collected over time (t) and channels (q). M(x,y) can be the object and C(x₁, Yₙ, q₀) can be the coil sensitivity at the location (xᵢ, yₙ) for channel q₀. Then the signal S can be provided by, for example:

S(q,t)=∫_{x,y}M(x,y)C(x,y,q)e^{-i2πk}ₓ(t)xdxdy [1]

Exemplary Procedure 1 can include a determination of one dimensional (“1D”) discrete Fourier transform of S to provide coil-sensitivity weighted projections. These projections can then be concatenated. (See, e.g., Eq. (2), and FIGS. 2A-2G). For example:

$$p ( {q}_{1} , k ) = F ( S ( {q}_{1} , t ) ) \qquad [ 2 a ]$$

$$P ( q , k ) = [ \begin{matrix}p ( {q}_{1} , k ) \\ p ( {q}_{2} , k ) \\ ⋮ \\ p ( {q}_{64} , k )\end{matrix} ] \qquad [ 2 b ]$$

Exemplary Procedure 2 can include, e.g., a determination of the exemplary line-intensity profiles by inverting the coil sensitivities for a particular column for all rows and channels. (See e.g., Eq. (3) and procedure of FIGS. 2A-2G). Thus, for example:

\hat{m}(x,yₙ)=C_{T}⁻¹(x,yₙ,q)P(q,kₙ)|n=0,1, . . . ,N−1 [3a]

\hat{M}(x,y)=[\hat{m}(x,y₁)\hat{m}(x,y₂) . . . m(x,y₁₂₈)] [3b]

In particular, FIGS. 2A-2G illustrate exemplary images of an exemplary reconstruction using the exemplary system, method, and computer-accessible medium according to an exemplary embodiment of the present disclosure. For examples, FIG. 2A illustrates five-cylinder in vitro phantom filled with water (W), vegetable oil (O), or Nickel Sulphate (N) doped water. The yellow triangle can indicate the readout gradient. FIG. 2B illustrates exemplary corresponding SER data from a 64 channel head coil according to an exemplary embodiment of the present disclosure. FIG. 2C illustrates exemplary coil sensitivity weighted projections with the red line marking the 64th column, for a reconstruction example, according to an exemplary embodiment of the present disclosure. FIG. 2C illustrates exemplary inverse of the relevant coil sensitivity matrix according to an exemplary embodiment of the present disclosure. FIG. 2E illustrates the 64th column of the projection data according to an exemplary embodiment of the present disclosure. FIG. 2F illustrates the resulting line-intensity from the underdetermined system in FIGS. 2D and 2E. FIG. 2G illustrates exemplary horizontal concatenation which can provide the image estimate according to an exemplary embodiment of the present disclosure.

Exemplary Procedure 3 can include, e.g., correcting the spatially varying point spread function (“PSF”) blurring using an ex U-net. (See, e.g., Reference 6). This can include, or can be equivalent to, characterizing the spatially varying PSF at each location and then inverting the entire PSF matrix. (See e.g., FIGS. 3C-3E). Due to the large size of the inversion, (e.g., 16384×16384), poor condition numbers can result. The exemplary deep learning (“DL”) equivalent U-net's training inputs can be generated by forward-modeling the reference scan image using Eqs. (1)-(3), and corrupting the image by randomly varying amplitude and noise. (See e.g., FIGS. 3F and 3G). The exemplary models can be trained per slice, and inferences can be determined on images from Eq. (3b). (See e.g., FIGS. 3H and 3I). In particular, FIGS. 3A-3G show exemplary images illustrating spatially varying point spread function deblurring according to an exemplary embodiment of the present disclosure. FIG. 3A illustrates an exemplary reference scan image (ref_im) from pre-scan (TR/TE=500/15 ms) according to an exemplary embodiment of the present disclosure. The reference image (ref_im) was used for coil sensitivity mapping. FIG. 3B illustrates an exemplary simulated single echo reconstruction (SER) image using Eqs. (1,2) according to an exemplary embodiment of the present disclosure. In this example embodiment, there is a contrast difference between reference scan and target image (see, e.g., procedure 3b, i.e., FIGS. 3H and 3I).

FIGS. 3C-3E illustrate exemplary deblurring procedures by spatially varying PSF matrix inversion (size 16384×16384) according to an exemplary embodiment of the present disclosure. In particular, FIG. 3C illustrates a test example (or image) depicting the vertical blurring in the SER recon. FIG. 3D shows an exemplary SER reconstruction. FIG. 3E illustrates an exemplary deblurred image by inverting a spatially varying PSF system matrix. FIGS. 3F and 3G illustrate exemplary a per slice training procedure using ref_im for DL PSF deblurring (i.e., step 3A). In this exemplary embodiment, samples were generated by varying amplitude and noise levels. FIGS. 3H and 3I show an exemplary inference procedure for DL PSF deblurring (i.e., step 3B). In particular, FIG. 3H illustrates the results of an exemplary SER recon reconstruction from 2 g, and FIG. 3I illustrations the corresponding inference using exemplary PSFdeblurNet.

### Exemplary Deep Learning

The exemplary system, method, and computer-accessible medium, according to an exemplary embodiment of the present disclosure, can utilize deep learning (“DL”) in order to perform a deblurring procedure on the output of the exemplary image. For example an exemplary DL model/procedure can be generated for each patient prior to generating the image. The exemplary DL model can be generated based on a reference scan of the particular patient being imaged. The reference scan can be generated, and a group of images can be generated based on the reference scan, which can be used to train and/or generated the exemplary DL model/procedure. In particular, the amplitude and noise levels can be varied (e.g., randomly or not randomly), in order to generate the group of images. These exemplary images, which have had their amplitude and noise levels varied, can then be used to train the exemplary DL model/procedure. After an initial image is generated for each patient using the exemplary procedure described above, the exemplary system, method, and computer-accessible medium can deblur the image using the specific DL model/procedure generated for the particular patient.

### Exemplary Results

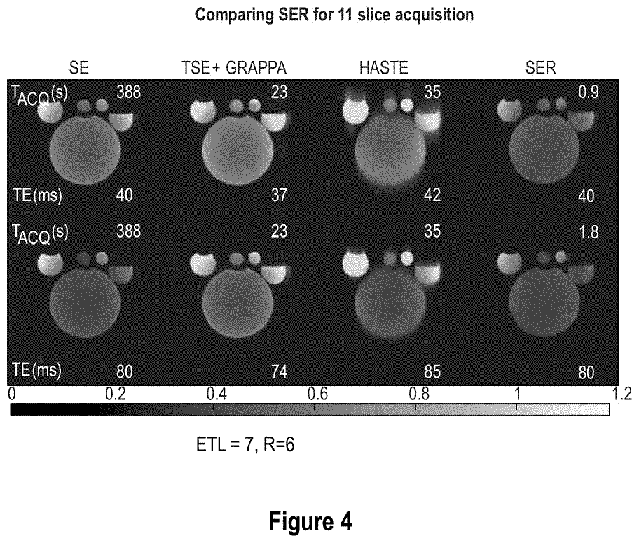

FIG. 4 shows a set of exemplary images comparing the exemplary SER with other reconstruction methods according to an exemplary embodiment of the present disclosure. In this exemplary set, a comparison of SER with other methods for an eleven slice acquisition is illustrated. The top row shows the reconstructed images for the gold standard spin-echo (SE), a turbo SE with an ETL of 7 and a GRAPPA factor of 6, a half-Fourier acquisition single-shot TSE (HASTE) at echo times (TE) shown in red font. The corresponding acquisition times (T_{acq}) are shown in yellow font and were recorded from the vendor's user interface. The bottom row shows acquisition times for the four methods at TEs close to 80 ms allowed by the vendor. SER images may not suffer from saturation or blurring artifacts.

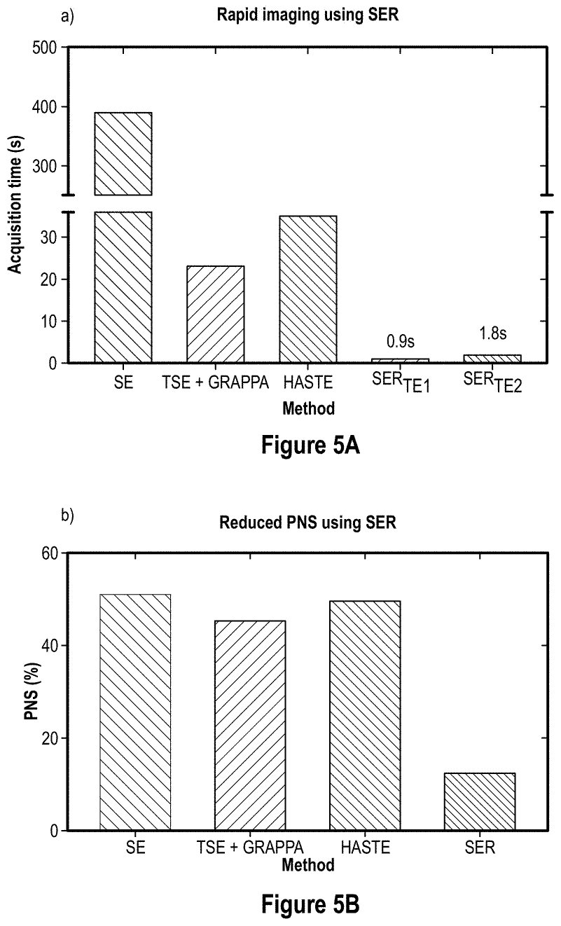

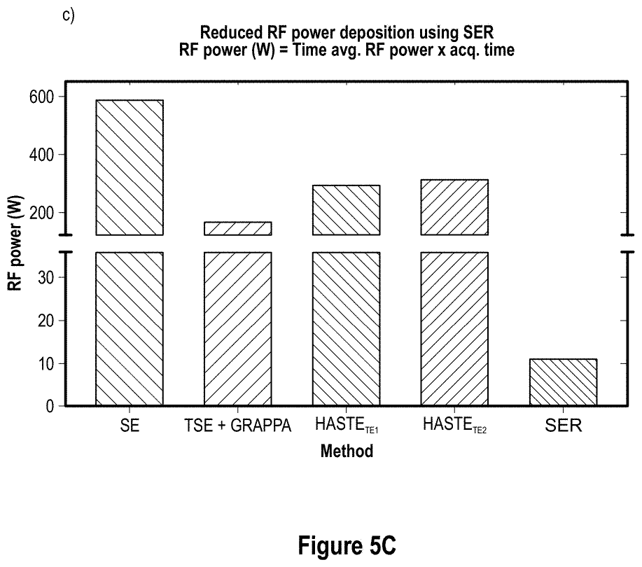

FIGS. 5A-5C show exemplary graphs comparing a performance of the exemplary SER with other methods according to an exemplary embodiment of the present disclosure. In particular, The graph of FIG. 5A illustrates that SER can provide, e.g., the fastest acquisition time for the four methods, depends on echo time (TE) rather than repetition time (TR) and phase encoding steps, and is faster than TSE+GRAPPA by an order of magnitude. The graph of FIG. 5B shows that SER can deliver the lowest RF power to the phantom among the methods, due to the one-time use of the 90° and 180° pulse. The graph of FIG. 5C illustrates that SER can be the most silent scan with the least peripheral nerve stimulation (PNS) percentage due to the one-time use of the readout gradient.

In addition to the exemplary features described above, the exemplary SER procedure(s) (i) may not require additional RF transmit channels for spatial encoding (see, e.g., FIGS. 1A and 1B); (ii) may not suffer from blurring artifacts associated with multi-echo sequences (see, e.g., FIGS. 4A-4G); and (iii) can achieve an R=Nᵥ. (See e.g., FIGS. 1A-2G, and 5A-5D). In contrast, acceleration methods such as GRAPPA typically provide a reduction factor R<<Nᵥ. The exemplary SER procedure(s) can utilize a reference image to learn coil sensitivities as part of a pre-scan similar to other partial parallel imaging methods. The exemplary SER approach(es) do not restrict its acquisition to SE or any particular pulse sequence. Thus, many pulse sequences and contrasts can be utilized. The exemplary SER procedure(s) can also significantly accelerate multi-contrast imaging, improve temporal resolution, and enhance SNR through increased averaging.

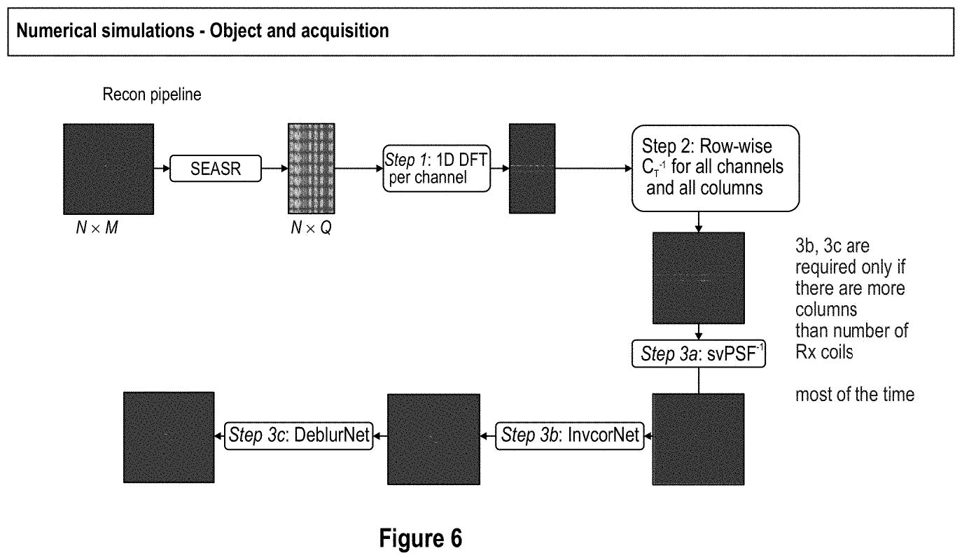

Further, FIG. 6 illustrates an exemplary reconstruction procedure according to an exemplary embodiment of the present disclosure.

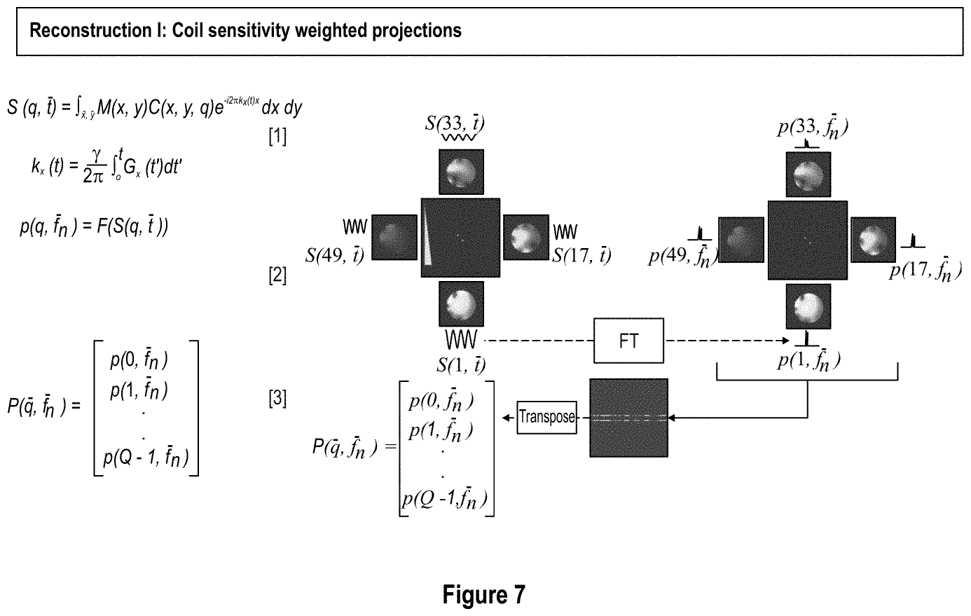

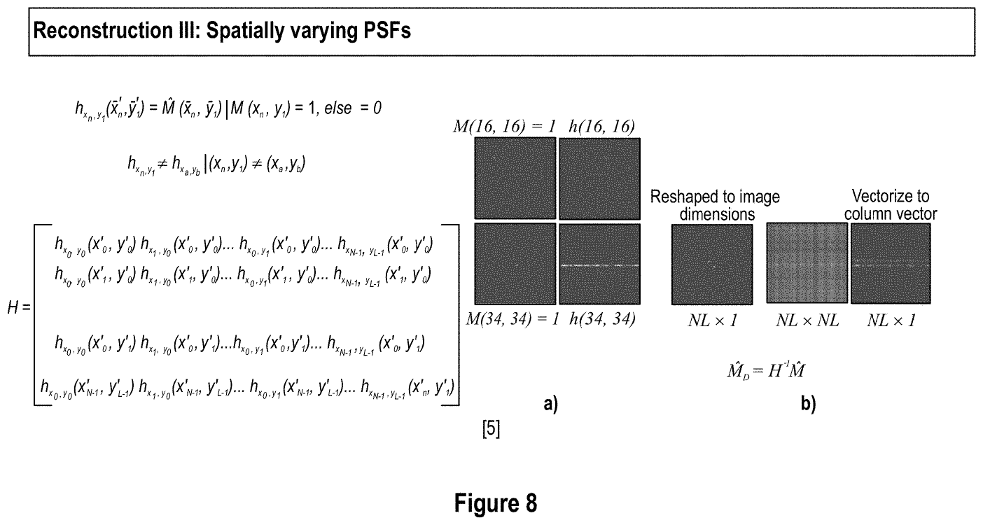

FIG. 7 shows exemplary coil sensitivity weighted projections according to an exemplary embodiment of the present disclosure. In addition, FIG. 8 illustrates an exemplary spatially varying PSF procedure according to an exemplary embodiment of the present disclosure.

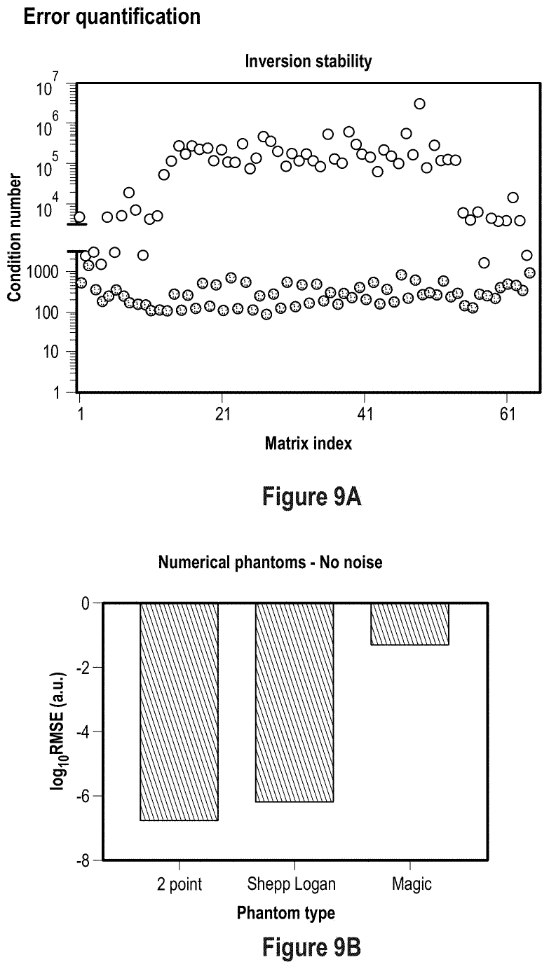

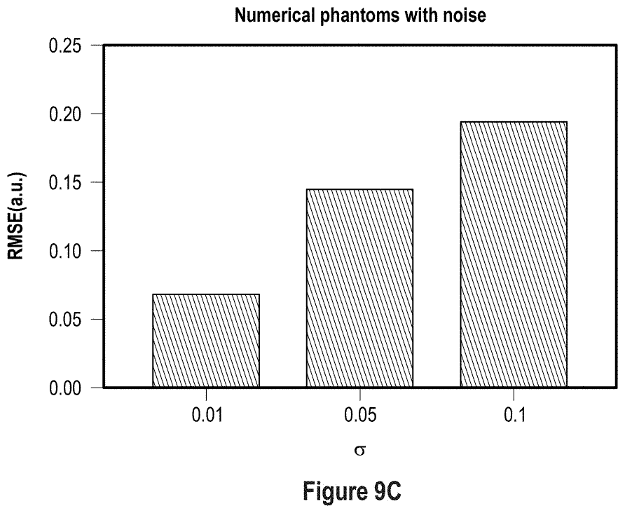

FIGS. 9A-9C illustrate exemplary error quantification graphs according to an exemplary embodiment of the present disclosure, with FIG. 9 providing the exemplary graph for inversion stability, the exemplary graph of FIG. 9B provides numerical phantoms without noise, and the exemplary graph of FIG. 9C is for numerical phantoms with noise.

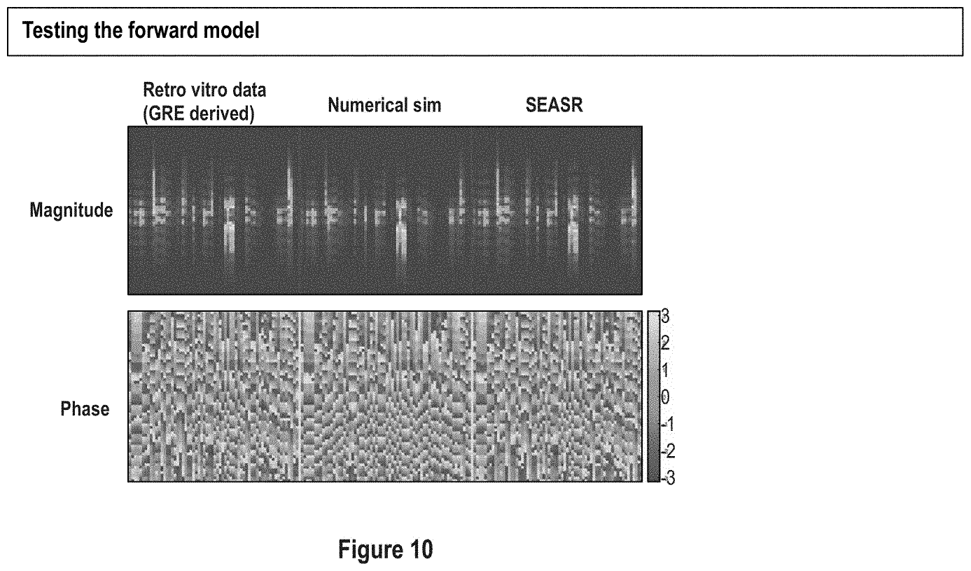

FIG. 10 shows exemplary test results according to an exemplary embodiment of the present disclosure. The top illustration of FIG. 10 provides the results for magnitude based on Retro vitro data (GRE derived), followed by for Numerical simulation, and that is followed by that for (SEARC). The bottom illustration provides the results for the phase.

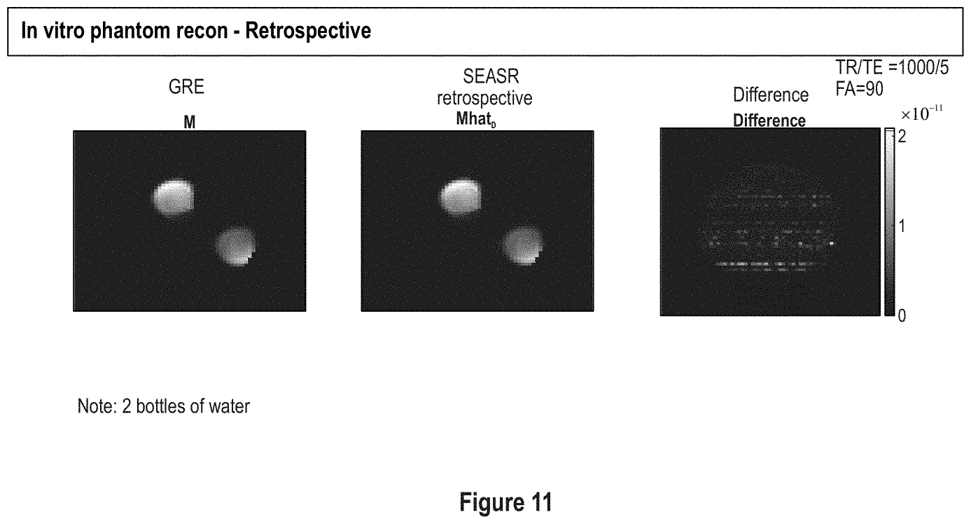

FIG. 11 illustrates exemplary retrospective images according to an exemplary embodiment of the present disclosure. In particular, the left illustration is provided for the GRE, the middle is for SEASR retrospective, and the right illustration is the difference therebetween.

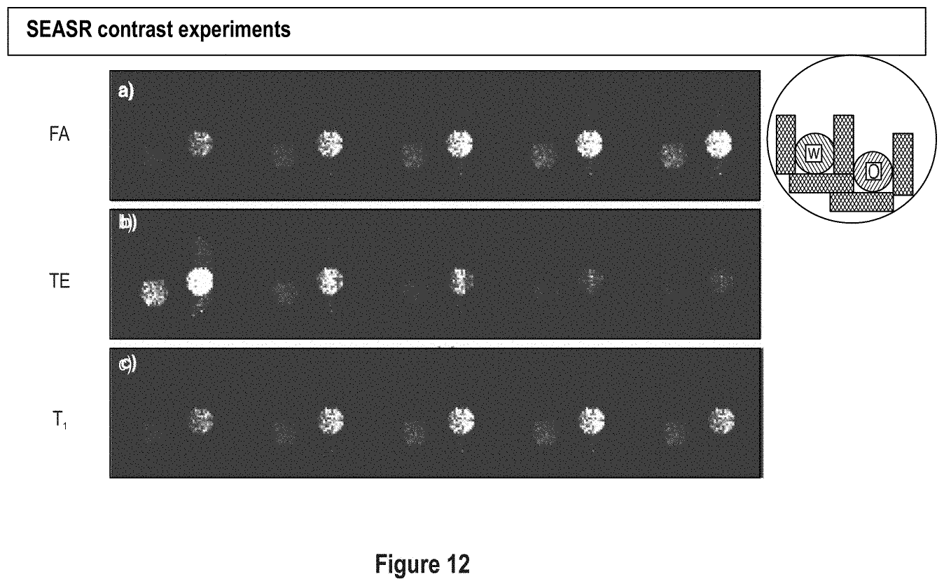

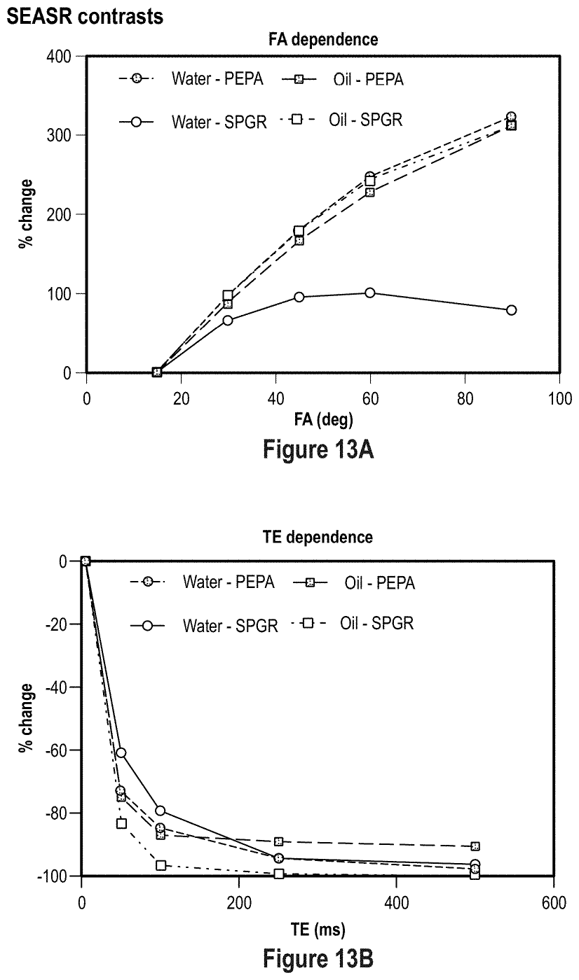

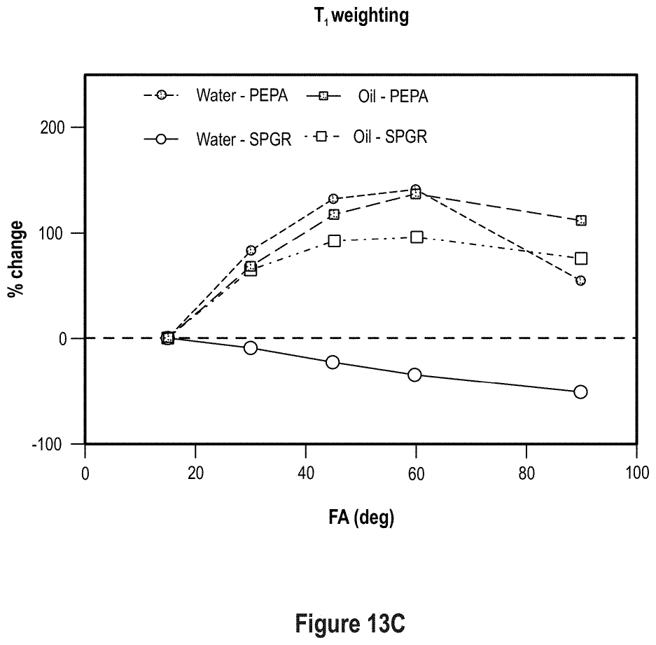

FIG. 12 provides a set of illustrations for the exemplary SEASR contrast experiments according to an exemplary embodiment of the present disclosure.
FIGS. 13A-13C shows exemplary SEASR contrast graphs according to an exemplary embodiment of the present disclosure. In particular, the left graph is for the FA dependance as a function of the percentage change, the middle graph is for the TE dependance as a function of the percentage change, and the right graph is for the T₁ weighing as a function of the percentage change.

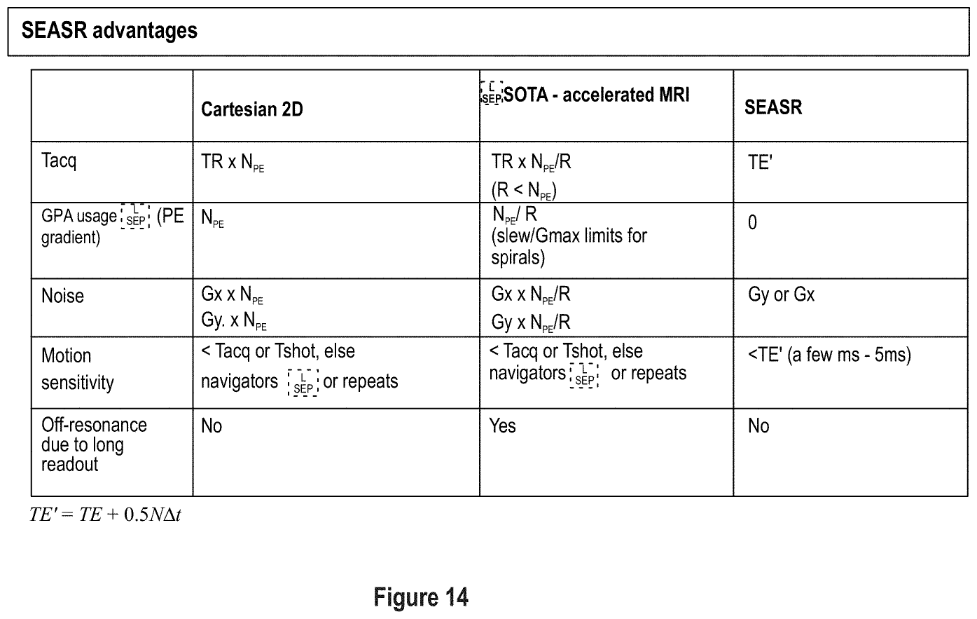

FIG. 14 illustrates a table listing exemplary advantages of SEASR procedure according to an exemplary embodiment of the present disclosure.

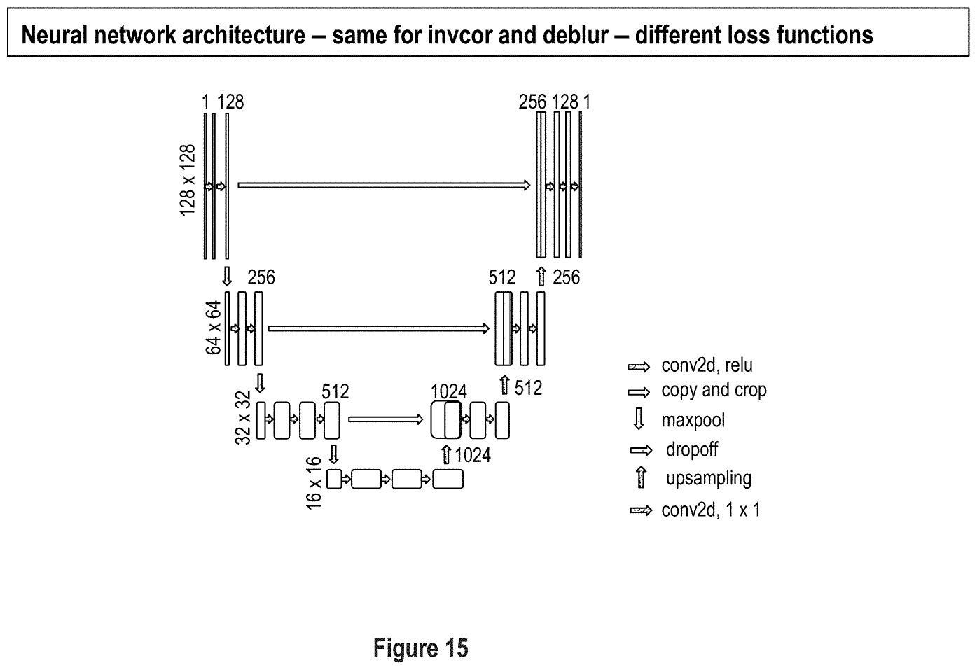

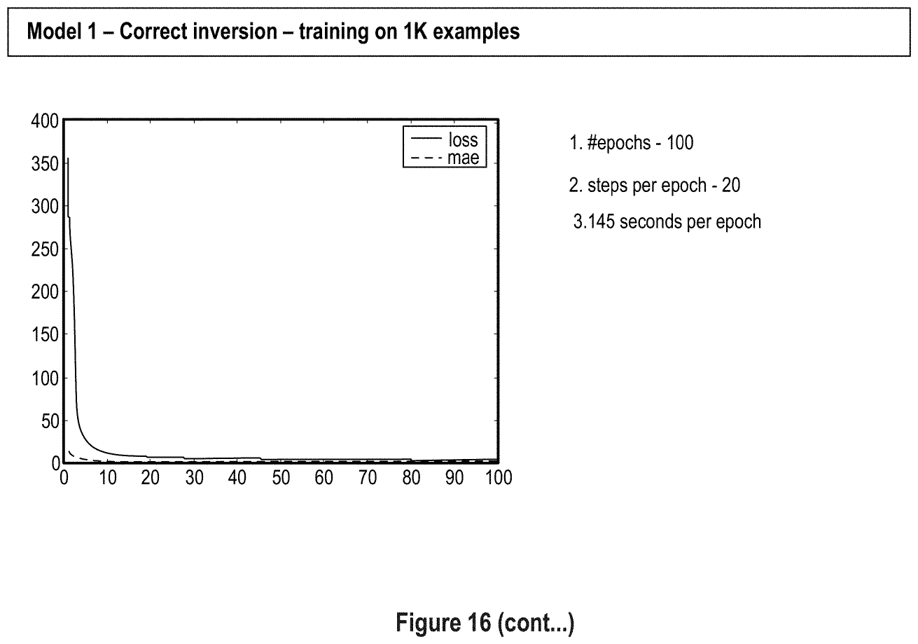

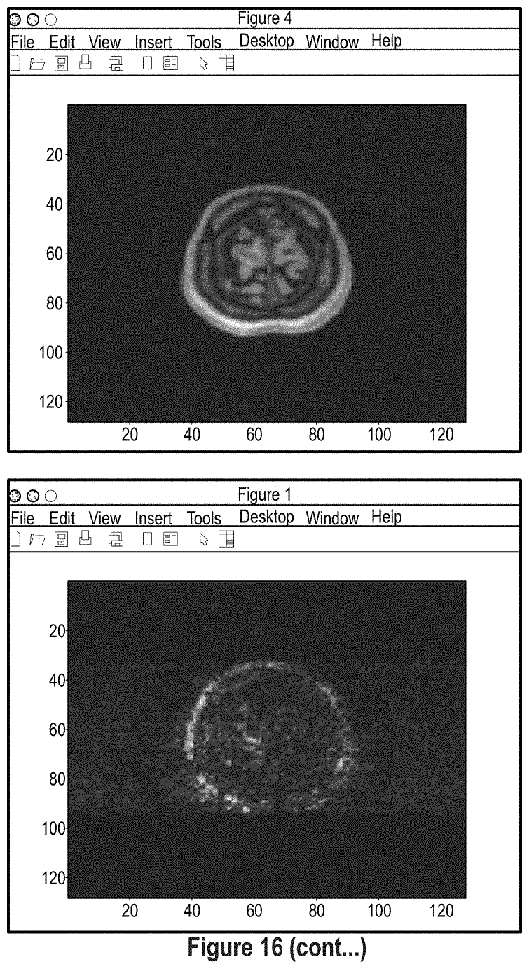

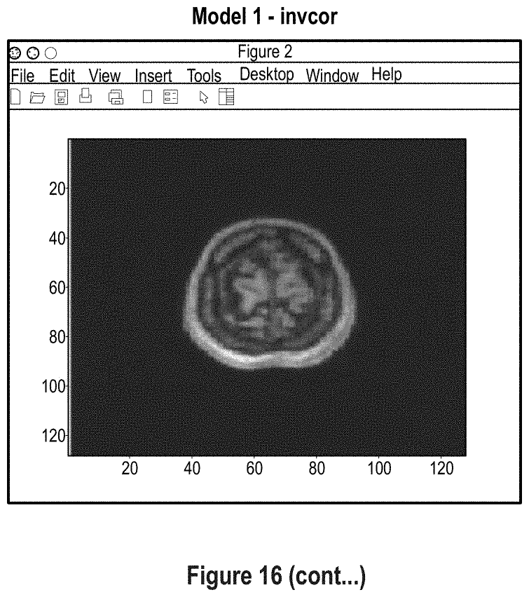

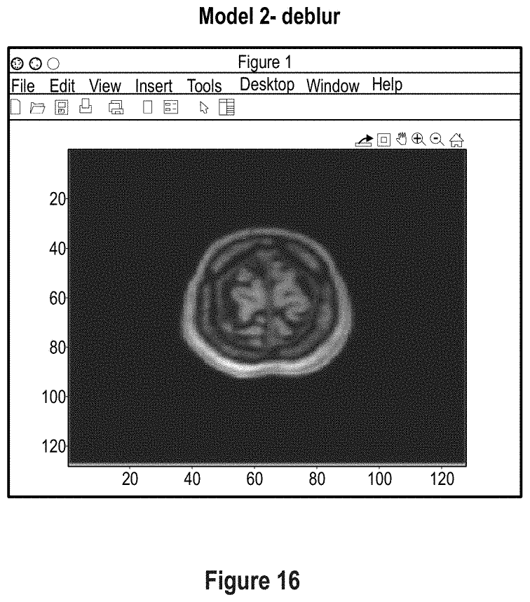

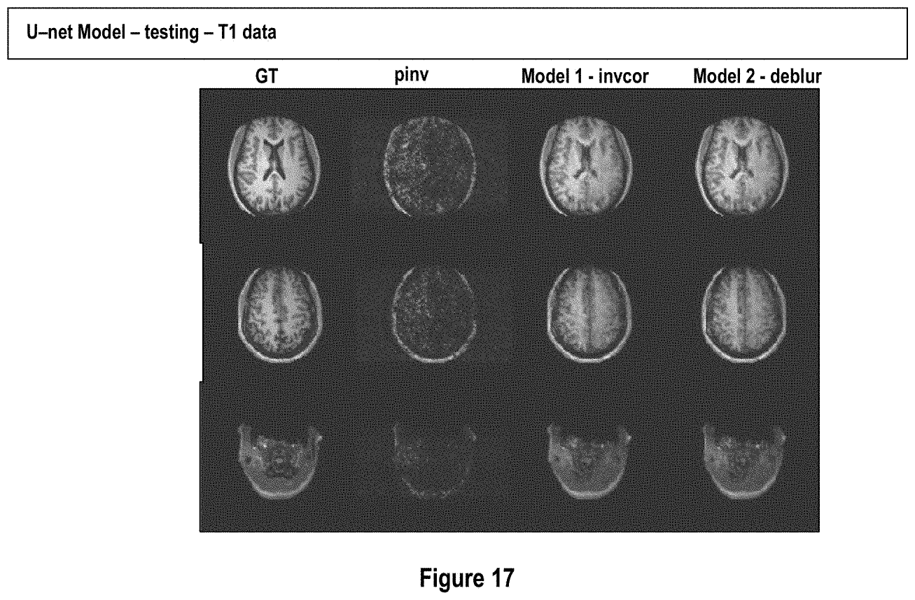

FIG. 15 shows an exemplary configuration of an exemplary neural network architecture according to an exemplary embodiment of the present disclosure that can be the same or similar for invcor and deblur, and with different loss functions.
FIG. 16 illustrates an exemplary training procedure according to an exemplary embodiment of the present disclosure for an exemplary model with the correct inversion and training on 1K examples.
FIG. 17 shows se set of exemplary images providing exemplary test results according to an exemplary embodiment of the present disclosure for an exemplary U-net model tested on T₁ data.

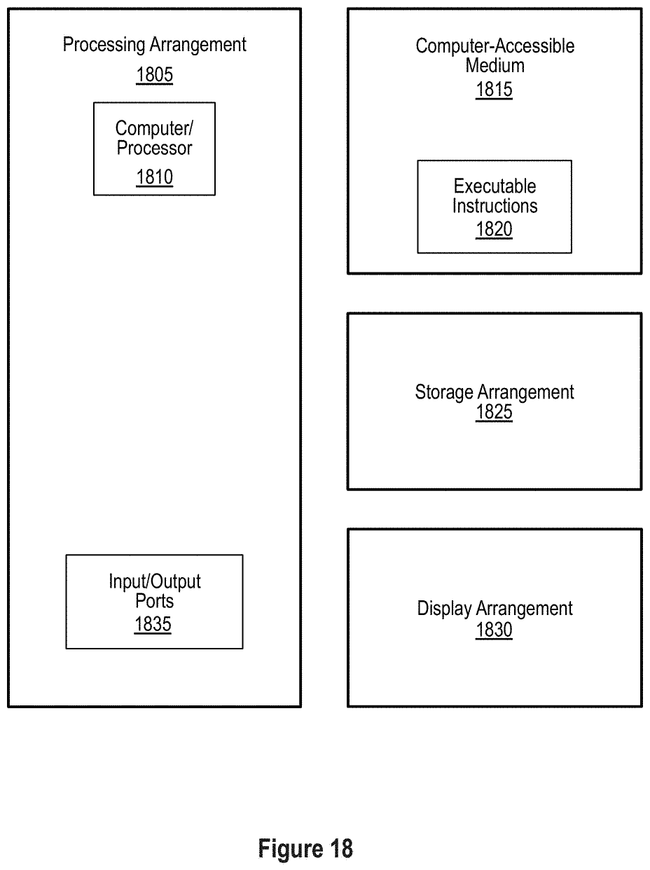

FIG. 18 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 1805. Such processing/computing arrangement 1805 can be, for example entirely or a part of, or include, but not limited to, a computer/processor 1810 that can include, for example one or more microprocessors, and use instructions stored on a computer-accessible medium (e.g., RAM, ROM, hard drive, or other storage device).

As shown in FIG. 18, for example a computer-accessible medium 1815 (e.g., as described herein above, a storage device such as a hard disk, floppy disk, memory stick, CD-ROM, RAM, ROM, etc., or a collection thereof) can be provided (e.g., in communication with the processing arrangement 1805). The computer-accessible medium 1815 can contain executable instructions 1820 thereon. In addition or alternatively, a storage arrangement 1825 can be provided separately from the computer-accessible medium 1815, which can provide the instructions to the processing arrangement 1805 so as to configure the processing arrangement to execute certain exemplary procedures, processes, and methods, as described herein above, for example.

Further, the exemplary processing arrangement 1805 can be provided with or include an input/output ports 1835, which can include, for example a wired network, a wireless network, the internet, an intranet, a data collection probe, a sensor, etc. As shown in FIG. 18, the exemplary processing arrangement 1805 can be in communication with an exemplary display arrangement 1830, which, according to certain exemplary embodiments of the present disclosure, can be a touch-screen configured for inputting information to the processing arrangement in addition to outputting information from the processing arrangement, for example. Further, the exemplary display arrangement 1830 and/or a storage arrangement 1825 can be used to display and/or store data in a user-accessible format and/or user-readable format.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification, drawings and claims thereof, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

### EXEMPLARY REFERENCES

The following references are hereby incorporated by reference, in their entireties:
[1] Hutchinson M, Raff U. Fast MRI data acquisition using multiple detectors. Magnetic Resonance in Medicine 1988
[2] McDougall M P, Wright S M. 64-Channel array coil for single echo acquisition magnetic resonance imaging. Magnetic Resonance in Medicine 2005
[3]) Lin F H, Wald L L, Ahlfors S P, Hämäläinen M S, Kwong K K, Belliveau J W. Dynamic magnetic resonance inverse imaging of human brain function. Magnetic Resonance in Medicine 2006
[4] Ravi, K. S., Potdar, S., Poojar, P., Reddy, A. K., Kroboth, S., Nielsen, J. F., Zaitsev, M., Venkatesan, R. and Geethanath, S., 2018. Pulseq-Graphical Programming Interface: Open source visual environment for prototyping pulse sequences and integrated magnetic resonance imaging algorithm development.Magnetic resonance imaging, 52, pp.9-15.
[5] Ravi, K. S., Geethanath, S. and Vaughan, J. T., 2019. PyPulseq: A Python Package for MRI Pulse Sequence Design. Journal of Open Source Software, 4(42), p.1725.
[6] Ronneberger, O., Fischer, P. and Brox, T., 2015, October. U-net: Convolutional networks for biomedical image segmentation. In International Conference on Medical image computing and computer-assisted intervention (pp. 234-241). Springer, Chain.

1. A non-transitory computer-accessible medium having stored thereon computer-executable instructions for reconstructing at least one portion of at least one image of at least one patient, wherein, when a computing arrangement executes the instructions, the computing arrangement is configured to perform procedures comprising:
receiving magnetic resonance imaging (MRI) information for the at least one patient;
generating a plurality of coil sensitivity weighted projections based on the MRI information;
inverting a column in the plurality of coil sensitivity weighted projections to generate inverted column information; and
reconstructing the at least one portion of the at least one image based on the inverted column information.

2. The computer-accessible medium of claim 1, wherein the computing arrangement is further configured to deblur the at least one portion of the at least one image.

3. The computer-accessible medium of claim 2, wherein the computing arrangement is configured to deblur the at least one portion of the at least one image using at least one deep learning procedure.

4. The computer-accessible medium of claim 3, wherein the computing arrangement is further configured to:
receive a reference scan of at least one part of the at least one patient; and
train the at least one deep learning procedure based on the reference scan.

5. The computer-accessible medium of claim 4, wherein the computing arrangement is further configured to:
generate a plurality of training images by varying at least one of (i) an amplitude of the reference scan, or (ii) a noise level of the reference scan; and
train the at least one deep learning procedure based on the plurality of training images.

6. The computer-accessible medium of claim 1, wherein the computing arrangement is further configured to:
(a) invert a further column in the plurality of coil sensitivity weighted projections to generate further inverted column information;
(b) reconstruct at least one further portion of the at least one image based on the further inverted column information; and
(c) repeat procedures (a) and (b) until the at least one image is reconstructed in its entirety.

7. The computer-accessible medium of claim 1, wherein the MRI information includes a signal collected over a time t and channels q.

8. The computer-accessible medium of claim 7, wherein the signal includes a coil sensitivity for each location of each of the channels q.

9. The computer-accessible medium of claim 8, wherein the plurality of coil sensitivity weighted projections are generated using a discrete Fourier transform of the signal.

10. The computer-accessible medium of claim 9, wherein the computing arrangement is further configured to concatenate the plurality of coil sensitivity weighted projections.

11. The computer-accessible medium of claim 8, wherein the inverting of the column in the plurality of coil sensitivity weighted projections comprises inverting coil sensitivities for a particular column for all rows and the channels q.

12. The computer-accessible medium of claim 1, wherein the inverted column information includes line-intensity profiles.

13. A system for reconstructing at least one portion of at least one image of at least one patient, comprising:
a computer hardware arrangement configured to:
receive magnetic resonance imaging (MRI) information for the at least one patient;
generate a plurality of coil sensitivity weighted projections based on the MRI information;
invert a column in the plurality of coil sensitivity weighted projections to generate inverted column information; and
reconstruct the at least one portion of the at least one image based on the inverted column information.

14-24. (canceled)

25. A method for reconstructing at least one portion of at least one image of at least one patient, comprising:
receiving magnetic resonance imaging (MRI) information for the at least one patient;
generating a plurality of coil sensitivity weighted projections based on the MRI information;
inverting a column in the plurality of coil sensitivity weighted projections to generate inverted column information; and
using a computer arrangement, reconstructing the at least one portion of the at least one image based on the inverted column information.

26. (canceled)

27. The method of claim 25, further comprising deblurring the at least one portion of the at least one image using at least one deep learning procedure.

28. The method of claim 27, further comprising:
receiving a reference scan of at least one part of the at least one patient; and
training the at least one deep learning procedure based on the reference scan.

29. The method of claim 28, further comprising:
generating a plurality of training images by varying at least one of (i) an amplitude of the reference scan, or (ii) a noise level of the reference scan; and
training the at least one deep learning procedure based on the plurality of training images.

30. The method of claim 25, at least one of:
wherein the MRI information includes a signal collected over a time t and channels q,
wherein the inverted column information includes line-intensity profiles, or
further comprising:
(a) inverting a further column in the plurality of coil sensitivity weighted projections to generate further inverted column information;
(b) reconstructing at least one further portion of the at least one image based on the further inverted column information; and
(c) repeating procedures (a) and (b) until the at least one image is reconstructed in its entirety.

31. (canceled)

32. The method of claim 30, wherein the signal includes a coil sensitivity for each location of each of the channels q.

33. The method of claim 32, wherein the plurality of coil sensitivity weighted projections are generated using a discrete Fourier transform of the signal, or wherein the inverting of the column in the plurality of coil sensitivity weighted projections comprises inverting coil sensitivities for a particular column for all rows and the channels q.

34. The method of claim 33, further comprising concatenating the plurality of coil sensitivity weighted projections.

35-36. (canceled)
